(19) United States
(12) Patent Application Publication
(10) Pub. No.: US 2007/0159071 A1
(43) Pub. Date: Jul. 12, 2007

(54) ORGANIC LIGHT EMITTING DIODE DEVICE

(75) Inventors: Chan-Jae Lee, Seoul (KR); Jeong-In Han, Seoul (KR); Dae-Gyu Moon, Yongin (KR)

Correspondence Address: SUGHRUE MION, PLLC, 2100 PENNSYLVANIA AVENUE, N.W., SUITE 800, WASHINGTON, DC, 20037, US

(73) Assignee: Korea Electronics Technology Institute

(21) Appl. No.: 11/562,065

(22) Filed: Nov. 21, 2006

(30) Foreign Application Priority Data
Dec. 28, 2005 (KR) 10-2005-0131277

(51) Int. Cl. H01L 51/00

(52) U.S. Cl. 313/504

(57) ABSTRACT

The present invention relates to a transparent electrode used in an OLED (Organic Light Emitting Diode), and in particular to a transparent electrode using a metal film for an OLED. That is, the present invention provides an OLED device, comprising: a substrate; an anode layer disposed on the substrate; a luminous organic layer disposed on the anode layer; and a cathode layer disposed on the luminous organic layer, wherein the cathode layer comprises a first metal layer consisting of a material selected from a group consisting of Ca, Mg, Ba, Sr and Y and a second metal layer consisting of a material selected from a group consisting of Ag and Al, and wherein the cathode layer has a thickness ranging from 7 nm to 40 nm.

### RELATED APPLICATIONS

The present disclosure relates to subject matter contained in priority Korean Application No. 10-2005-0131277, filed on 28 Dec. 2005 which is herein expressly incorporated by reference in its entirety.

### BACKGROUND OF THE INVENTION

1. Field of the Invention

The present invention relates to a transparent electrode used in an OLED (Organic Light Emitting Diode), and in particular to a transparent electrode using a metal film for an OLED.

2. Description of the Related Art

FIG. 1 is a cross-sectional view illustrating a conventional OLED device.

Referring to FIG. 1, an anode is formed on a substrate, and an organic layer for a luminescence, a cathode consisting of a metal and an ITO are sequentially stacked thereon.

Since an OLED is driven by a current, more than four transistors and capacitors are required for driving a single pixel in order to drive an active matrix OLED. Therefore, an aperture ratio is reduced because an area occupied by driving devices is increased due to an in crease in numbers of the driving devices in the pixel, resulting in an increase in the power consumption and the reduction of life time of a panel. In order to solve this problem, a top emission method wherein a device driving circuit is installed in a substrate and the OLED device is disposed on the device driving circuit has been proposed. In order to manufacture such device, a cathode should be transparent so that a light travels in a direction opposite to a substrate. The conventional transparent cathode reduces the life span of the device since an inorganic material such as ITO (Indium-Tin Oxide) is deposited via a sputtering for a transmittance and electrical conductivity.

The ITO which is widely used as the transparent electrode employs the sputtering method in order to obtain a certain characteristic. However, when the ITO is deposited on the OLED device via the sputtering method, an organic layer is damaged by an impact of a particle having an energy during the sputtering process, thereby degrading a characteristic of the device. Moreover, since a work function of the ITO is high, a characteristic of an electron injection to the organic layer is deteriorated when the ITO is used as the cathode of the OLED.

In order to solve these problems, a thin metal film is deposited prior to the deposition of the ITO. However, the problem of damaging the organic layer during the deposition of the ITO still remains although the characteristic of the electron injection is improved to a certain degree. Moreover, the thin metal film is thicker than a certain thickness, the thin metal film is not suitable to be used as an electrode for a top emission which utilizes a light passing through the cathode electrode because the electrode reflects most of the light. In order to overcome this problem, a method wherein the electrode is formed to be very thin so that the light may pass through the electrode has been proposed. However, a resistance increases as the thickness is reduced, and the electrode also becomes unstable physically and chemically.

Another drawback of using the ITO is that a transmittance and a resistance of an ITO film is radically changed due to a change in a composition of the ITO film according to a partial pressure of an oxygen and a temperature during the sputtering process.

Moreover, additional process equipments for the deposition of the ITO are required, resulting in a high manufacturing cost and a low productivity.

### SUMMARY OF THE INVENTION

It is an object of the present invention to provide a transparent electrode and a method for manufacturing the same wherein the ITO is not used so that the luminous organic layer and the substrate are not damaged.

It is an object of the present invention to provide a transparent electrode and a method for manufacturing the same having an improved electrical conductivity and transmittance.

It is an object of the present invention to provide a transparent electrode and a method for manufacturing the same which may be manufactured using a less expensive material and a simpler equipment compared to the conventional art.

In order to achieve the object of the present invention, there is provided an OLED device, comprising: a substrate; an anode layer disposed on the substrate; a luminous organic layer disposed on the anode layer; and a cathode layer disposed on the luminous organic layer, wherein the cathode layer comprises a first metal layer consisting of a material selected from a group consisting of Ca, Mg, Ba, Sr and Y and a second metal layer consisting of a material selected from a group consisting of Ag and Al, the first metal layer being disposed on the luminous organic layer, and wherein the cathode layer has a thickness ranging from 7 nm to 40 nm. The OLED device may further comprise an oxide film of the first metal layer and the second metal layer, the oxide film being disposed between the first metal layer and the second metal layer.

The OLED device in accordance with the present invention may further comprise a coating layer on the second metal layer, coating layer being selected from a group consisting of SiO2, Ta2O5, SiON, Si3N4, Al2O3, polymide and parylene.

In order to achieve the object of the present invention, there is also provided an OLED device, comprising: a substrate; a first metal layer disposed on the substrate, the first metal layer consisting of a material selected from a group consisting of Ca, Mg, Ba, Sr and Y; a second metal layer disposed on the first metal layer, the second metal layer consisting of a material selected from a group consisting of Ag and Al; a luminous organic layer disposed on the second metal layer; a third metal layer disposed on the organic layer, the third metal layer consisting of a material selected from the group consisting of Ca, Mg, Ba, Sr and Y; and a fourth metal layer disposed on the third metal layer, the fourth metal layer consisting of a material selected from the group consisting of Ag and Al, wherein a total thickness of the first metal layer and the second metal layer, and a total thickness of the third metal layer and the fourth metal layer range from 7 nm to 40 nm, respectively.

In order to achieve the object of the present invention, there is also provided a method for manufacturing an electronic display including an OLED device, the method comprising: forming a first metal layer consisting of a material selected from a group consisting of Ca, Mg, Ba, Sr and Y; and forming a second metal layer consisting of a material selected from a group consisting of Ag and Al, wherein a thickness of the second metal layer ranges from 5 nm to 20 nm and a total thickness of the first metal layer and the second metal layer is equal to or less than 40 nm.

The method in accordance with the present invention may further comprise oxidizing a surface of the first metal layer at an interface of the first metal layer and the second metal film after forming the first metal layer or forming a transparent protective film after forming the second metal layer.

### BRIEF DESCRIPTION OF THE DRAWINGS

FIG. 1 is a cross-sectional view illustrating a conventional OLED device.

FIG. 2 is a cross-sectional view illustrating an OLED device including a transparent cathode consisting of two metal layers in accordance with a preferred embodiment of the present invention.

FIG. 3 is a cross-sectional view illustrating an OLED device including a transparent cathode consisting of two metal layers in accordance with another embodiment of the present invention.

FIG. 4 is a graph illustrating a transmittance of a transparent metal electrode in accordance with the present invention.

### DETAILED DESCRIPTION OF THE INVENTION

The present invention will now be described in detail with reference to the accompanied drawings.

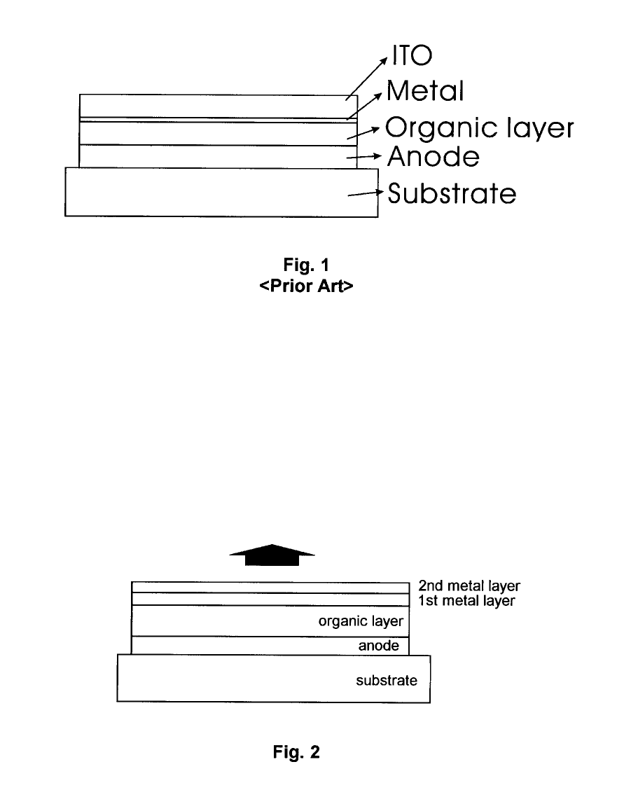

FIG. 2 is a cross-sectional view illustrating an OLED device including a transparent cathode consisting of two metal layers in accordance with a preferred embodiment of the present invention.

The present invention, contrary to the conventional art which employs the ITO for a transparent cathode, employs two metal layers.

As shown in FIG. 2, an anode and an organic layer are formed on the substrate. Thereafter, a first metal layer and a second metal layer are sequentially stacked thereon.

A thermal evaporation method may be used to deposit the metal layers instead of a sputtering method which damages the organic layer and the substrate so as to reduce a defective rate of the device and to form the first metal layer and the second metal layer using an equipment less expensive than a sputtering equipment.

The first metal layer which is in direct contact with the organic layer is formed using a metal having a low work function, Ca, Mg, Ba, Sr or Y in order to improve a characteristic of an electron injection. Since the metal layer should let light pass through, the layer should have a small thickness, for example 3-20 nm. However, an optimal thickness may vary according to a relationship to the second metal layer.

The second metal layer is formed using Ag or Al. a thickness of the second metal layer ranges from 5-20 nm, and the thickness may be varied according to a relationship to the first metal layer. The second metal layer protects the first metal layer from a reaction of the first metal layer to an atmosphere, improves a transmittance, and reduces an electrical resistance.

It should be noted that the transmittance is improved to 60-90% by depositing the second metal layer on the first metal layer while the first metal layer alone has the transmittance of 15 to 50% in a visible light region.

On the other hand, although it is known that a metal has the transmittance when the metal has a thickness ranging from ten to tens of nanometers, the transmittance is degraded when the metal is deposited to have a thickness ranging from 3-5 nm depending on a material. Therefore, it is preferable that the first metal layer and the second metal layer are deposited to have the thickness disclosed above.

The inventor of the present invention has discovered after a long experiment that the transmittance is optimal when a total thickness of the first metal layer and the second metal layer ranges from 7 to 40 nm, and more preferably 15 to 25 nm.

On the other hand, an oxide film may be formed to improve the transmittance. A portion of or the entire first metal layer may be oxidized to form a CaOₓ layer (where x is an oxidation number), and the second metal layer is then deposited using Ag or Al.

In addition, the transmittance may be improved by oxidizing the second metal layer. An AgOₓ layer (where x is an oxidation number) formed by oxidizing a portion of or the entire second metal layer has an improved transmittance, and improves the transmittance of the transparent electrode. An arrow in FIG. 2 denotes a direction of an emission of light.

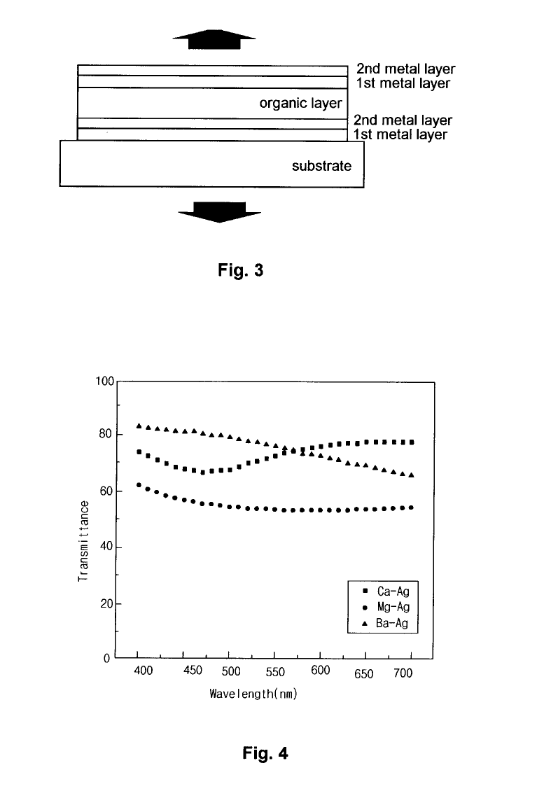

FIG. 3 is a cross-sectional view illustrating an OLED device including a transparent cathode consisting of two metal layers in accordance with another embodiment of the present invention, wherein a double side luminous OLED which employs two transparent electrodes at both sides is disclosed as well as an OLED which emits a light to one direction.

As shown in FIG. 3, a cathode comprising a first metal layer and a second metal layer is formed on a transparent substrate. Thereafter, an organic layer a luminescence, a third metal layer and a fourth metal layer are sequentially formed thereon. Specifically, the OLED device comprises the first metal layer disposed on the substrate and consisting of a material selected from a group consisting of Ca, Mg, Ba, Sr and Y, the second metal layer disposed on the first metal layer and consisting of a material selected from a group consisting of Ag and Al, the luminous organic layer disposed on the second metal layer, the third metal layer disposed on the organic layer and consisting of a material selected from the group consisting of Ca, Mg, Ba, Sr and Y, and the fourth metal layer disposed on the third metal layer and consisting of a material selected from the group consisting of Ag and Al. A total thickness of the first metal layer and the second metal layer, and a total thickness of the third metal layer and the fourth metal layer range from 7 nm to 40 nm, respectively. Preferably, the metal layers are deposited by the thermal evaporation method.

In accordance with the embodiment, it is advantageous that an electrical and optical design is facilitated by using an identical electrode for the anode and the cathode. In addition, since a light emitted by the organic layer is radiated in two directions, which are denoted as bold arrows in FIG. 3, with respect to the substrate, the double side luminous OLED may be embodied.

FIG. 4 is a graph illustrating a transmittance of a transparent metal electrode in accordance with the present invention.

As shown, the transparent electrode manufactured according to the above-described methods has more than 60% of transmittance in cases of Ca—Ag, Ba—Ag, Ma-Ag combinations.

While the present invention has been particularly shown and described with reference to the preferred embodiment thereof, it will be understood by those skilled in the art that various changes in form and details may be effected therein without departing from the spirit and scope of the invention as defined by the appended claims. For instance, the transparent electrode described herein may be used for every field wherein the transparent electrode is used in addition to the OLED. Particularly, the transparent electrode of the present invention may be used in an LCD, a PDP, a FED, and a touch panel to replace the ITO. Therefore, and scope of the present invention should be defined by the appended claims.

As described above, in accordance with the present invention, the transparent metal electrode which has a larger ductility than an inorganic layer is used to improve a stability while the ITO used in a flexible display as the transparent electrode is apt to crack due to a difference in a thermal and mechanical characteristics with a plastic film which is a substrate.

A life time and a luminous characteristic are degraded due to a damage in the organic layer by ITO particles during an ITO deposition when the conventional art is applied to the top emission OLED while two types of metal layers are deposited by the thermal evaporation method in accordance with the present invention in order to prevent the damage of the organic layer. In addition, since the thermal evaporation method is already in use for a general OLED manufacturing process, a separate sputtering process and equipment are not required, thereby reducing a manufacturing cost and improving a productivity.

What is claimed:

1. An OLED device, comprising:
a substrate;
an anode layer disposed on the substrate;
a luminous organic layer disposed on the anode layer; and
a cathode layer disposed on the luminous organic layer,
wherein the cathode layer comprises a first metal layer consisting of a material selected from a group consisting of Ca, Mg, Ba, Sr and Y and a second metal layer consisting of a material selected from a group consisting of Ag and Al, the first metal layer being disposed on the luminous organic layer, and
wherein the cathode layer has a thickness ranging from 7 nm to 40 nm.

2. The device in accordance with claim 1, further comprising an oxide film of the first metal layer, the oxide film being disposed between the first metal layer and the second metal layer.

3. The device in accordance with claim 1, further comprising an oxide film of the second metal layer, the oxide film being disposed between the first metal layer and the second metal layer.

4. The device in accordance with claim 1, further comprising an oxide film of the first metal layer and the second metal layer, the oxide film being disposed between the first metal layer and the second metal layer.

5. The device in accordance with one of claims 1 through 4, further comprising a coating layer on the second metal layer, coating layer being selected from a group consisting of SiO2, Ta2O5, SiON, Si3N4, Al2O3, polymide and parylene.

6. An OLED device, comprising:
a substrate;
a first metal layer disposed on the substrate, the first metal layer consisting of a material selected from a group consisting of Ca, Mg, Ba, Sr and Y;
a second metal layer disposed on the first metal layer, the second metal layer consisting of a material selected from a group consisting of Ag and Al;
a luminous organic layer disposed on the second metal layer;
a third metal layer disposed on the organic layer, the third metal layer consisting of a material selected from the group consisting of Ca, Mg, Ba, Sr and Y; and
a fourth metal layer disposed on the third metal layer, the fourth metal layer consisting of a material selected from the group consisting of Ag and Al,
wherein a total thickness of the first metal layer and the second metal layer, and a total thickness of the third metal layer and the fourth metal layer range from 7 nm to 40 nm, respectively.

7. The device in accordance with claim 6, further comprising a first oxide film formed by oxidizing a surface of the first metal layer or a second oxide film formed by oxidizing a surface of the second metal layer, the first and the second oxide films being disposed between the first metal layer and the second metal layer.

8. The device in accordance with claim 6, further comprising a third oxide film formed by oxidizing a surface of the third metal layer or a fourth oxide film formed by oxidizing a surface of the fourth metal layer, the third and the fourth oxide films being disposed between the third metal layer and the fourth metal layer.

9. A method for manufacturing an electronic display including an OLED device, the method comprising:
forming a first metal layer consisting of a material selected from a group consisting of Ca, Mg, Ba, Sr and Y; and
forming a second metal layer consisting of a material selected from a group consisting of Ag and Al, wherein a thickness of the second metal layer ranges from 5 nm to 20 nm and a total thickness of the first metal layer and the second metal layer is equal to or less than 40 nm.

10. The method in accordance with claim 9, further comprising oxidizing a surface of the first metal layer at an interface of the first metal layer and the second metal film after forming the first metal layer.

11. The method in accordance with claim 9, further comprising forming a transparent protective film, after forming the second metal layer.
